(19) United States
(12) Patent Application Publication
(10) Pub. No.: US 2013/0094130 A1
(43) Pub. Date: Apr. 18, 2013

(54) MOTHER BOARD AND FIXING MODULE THEREOF

(71) Applicant: ASUSTeK Computer Inc., (US)

(72) Inventors: Shang-Li YANG, Taipei (TW); Ji-Kuang TAN, Taipei (TW); Bing-Min LIN, Taipei (TW)

(73) Assignee: ASUSTEK COMPUTER INC.

(21) Appl. No.: 13/627,459

(22) Filed: Sep. 26, 2012

(30) Foreign Application Priority Data
Oct. 12, 2011 (TW) 100137055

(51) Int. Cl. H05K 7/20; G06F 1/20; H05K 5/02; G06F 1/16

(52) U.S. Cl. 361/679.02; 312/223.1; 312/223.2

(57) ABSTRACT

A mother board comprises a circuit board, an electronic device, and a fixing module. The circuit board includes a first surface, a second surface, a plurality of first fixing holes, and a plurality of second fixing holes. The electronic device is disposed on the first surface. The fixing module includes an upper casing, a first back casing, and a second back casing. The upper casing is disposed on the first surface and includes a plurality of holes. The first back casing is disposed on the second surface and includes a plurality of first fixing elements which are passed through the first fixing holes to connect to the holes of the upper casing. The second back casing is disposed on the second surface and includes a plurality of second fixing elements which are connected to the second fixing holes.

### CROSS REFERENCE TO RELATED APPLICATIONS

This Non-provisional application claims priority under 35 U.S.C. §119(a) on Patent Application No(s). 100137055 filed in Taiwan, Republic of China on Oct. 12, 2011, the entire contents of which are hereby incorporated by reference.

### BACKGROUND OF THE INVENTION

1. Field of Invention

The invention relates to a mother board and a fixing module thereof and, in particular, to a mother board and a fixing module thereof applied to a heat dissipating device.

2. Related Art

Temperature is a big factor, more than 55%, to cause an electronic device breakdown. When the temperature rises for per 10° C., the reliability will be lowered down to half. Accordingly, the heat-dissipation is conducted for controlling the temperature so that the electronic device can operate under the best condition.

In the computer, the central processing unit (CPU) with its temperature is always a focal point. When the CPU operates under the lower temperature, the power can be more saved with better efficiency. Accordingly, a heat-dissipation device is usually equipped around the CPU to dissipate the heat generated by the CPU, so that the CPU can be maintained for a lower temperature.

However, different type of CPU is usually cooperated with different type of heat dissipating device. Hence, if the user wants to replace the CPU, the heat dissipating device needs to be replaced as well. Besides, the user can not select another type of heat dissipating device to replace the original one.

### SUMMARY OF THE INVENTION

The present invention provides a mother board and a fixing module thereof that can match different type of heat dissipating device, so that the user or the firm can replace the heat dissipating device according to the performance of the electronic device or the required level of heat dissipation. Therefore, the heat generated by the electronic device can be properly dissipated to achieve the best heat dissipating efficiency.

The present invention provides a mother board that includes a circuit board, an electronic device, and a fixing module. The circuit board includes a first surface, a second surface, a plurality of first fixing holes, and a plurality of second fixing holes. The electronic device is disposed on the first surface. The fixing module includes an upper casing, a first back casing, and a second back casing. The upper casing is disposed on the first surface and includes a plurality of holes. The first back casing is disposed on the second surface and includes a plurality of first fixing elements which are passed through the first fixing holes to connect to the holes of the upper casing. The second back casing is disposed on the second surface and includes a plurality of second fixing elements which are connected to the second fixing holes.

In a preferred embodiment of the invention, the first fixing holes are closer to the electronic device than the second fixing holes.

In a preferred embodiment of the invention, the electronic device is a central processing unit (CPU).

In a preferred embodiment of the invention, the first back casing and the second back casing are integrally formed as one piece, or separate pieces.

In a preferred embodiment of the invention, the first fixing elements are screws, and the second fixing elements are troughs or holes. The holes of the upper casing are threaded holes.

In a preferred embodiment of the invention, the mother board further comprises a heat dissipating device which is connected to the second fixing elements disposed corresponding to the second fixing holes.

The present invention further provides a fixing module for fixing an electronic device and a heat dissipating device to a circuit board. The fixing module comprises an upper casing, a first back casing, and a second back casing. The upper casing includes a plurality of holes. The first back casing is disposed opposite to the upper casing and includes a plurality of first fixing elements which are connected to the holes of the upper casing. The second back casing is connected to the first back casing and includes a plurality of second fixing elements.

As mentioned above, the first back casing and the second back casing can be integrally formed as one piece or can be separate pieces. By the various combinations of different aspects of the first back casing and the second back casing, the different types of heat dissipating device can be fixed by the fixing module. Accordingly, the user or the firm can select the required heat dissipating device according to the performance of the electronic device or the required level of heat dissipation, so that the electronic device can be provided with the best heat dissipating efficiency, ensuring the life cycle and operating efficiency thereof.

Compared with the prior art, the first back casing for fixing the electronic device is disposed on the second surface of the circuit board, and the second back casing for fixing the heat dissipating device is also disposed on the second surface of the circuit board. Besides, if the second back casing is replaced by another one of different aspect (such as size or shape), the fixing module of the invention can fix other types of heat dissipating device, so that the electronic device can be provided with the best heat dissipating efficiency, ensuring the life cycle and operating efficiency thereof.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic exploded diagram of a mother board according to a preferred embodiment of the invention;

FIG. 2 is an exploded diagram of another aspect of the mother board of the invention; and

FIG. 3 is an exploded diagram of another aspect of the mother board of the invention.

### DETAILED DESCRIPTION OF THE INVENTION

The present invention will be apparent from the following detailed description, which proceeds with reference to the accompanying drawings, wherein the same references relate to the same elements.

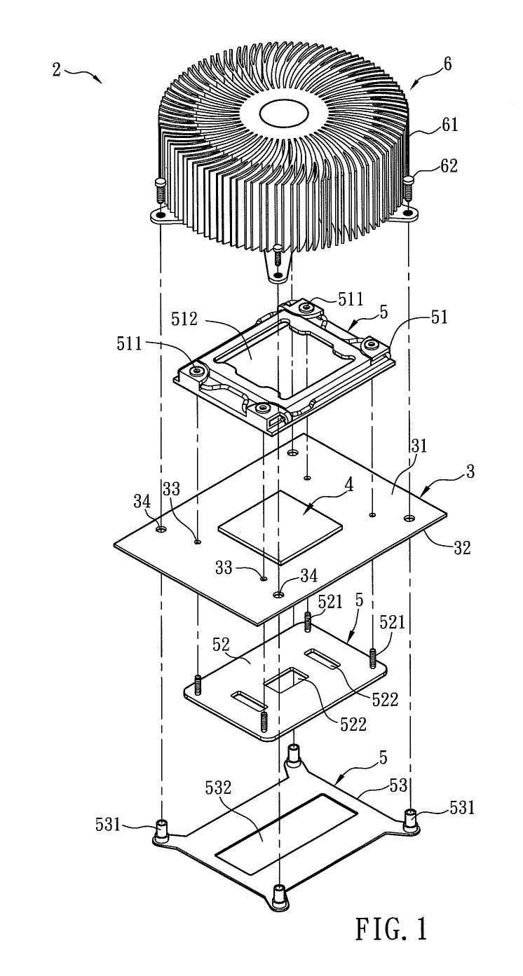

FIG. 1 is a schematic exploded diagram of a mother board according to a preferred embodiment of the invention. The mother board 2 includes a circuit board 3, an electronic device 4, and a fixing module 5. The mother board 2 can be applied to the computer for example, but not for limiting the scope of the invention.

The circuit board 3 has a first surface 31 and a second surface 32, which are opposite sides of the circuit board 3. The circuit board 3 further includes a plurality of first fixing holes 33 and a plurality of second fixing holes 34, and in the embodiment there are four first fixing holes 33 and four second fixing holes 34 for example. The first fixing holes 33 and the second fixing holes 34 are disposed through the circuit board 3, and are circle-shaped for example. The first fixing holes 33 and the second fixing holes 34 can have the same or different size, depending on the application or the design. In the embodiment, the second fixing holes 34 are disposed at the outside of the first fixing holes 33. The first fixing holes 33 are closer to the electronic device 4 than the second fixing holes 34.

The electronic device 4 is disposed on the first surface 31 of the circuit board 3, and disposed among the first holes 33. In the embodiment, the electronic device 4 is illustrated as a central processing unit (CPU), but not for limiting the scope of the invention. In other embodiments, the electronic device 4 can be other kind of device easy to generate the heat.

The fixing module 5 includes an upper casing 51, a first back casing 52, and a second back casing 53. The upper casing 51 is disposed on the first surface 31 of the circuit board 3 to fix the electronic device 4. The upper casing 51 has a plurality of holes 511 and an opening 512. The holes 511 are disposed corresponding to the first fixing holes 33 of the circuit board 3 with the same size and shape as the first fixing holes 33. In the embodiment, the holes 511 of the upper casing 51 are threaded holes for example.

The first back casing 52 is disposed on the second surface 32 of the circuit board 3, and is connected to the upper casing 51 for strengthening the connection of the electronic device 4. In the embodiment, the first back casing 52 includes a plurality of first fixing elements 521 and a plurality of openings 522. The first fixing elements 521 are disposed corresponding to the first fixing holes 33 of the circuit board 3, and can be passed through the first fixing holes 33 to connect the holes 511 of the upper casing 51. In the embodiment, the first fixing element 521 is illustrated as a screw for example. The openings 522 are disposed corresponding to the electronic devices (not shown) that are disposed on the second surface 32 of the circuit board 3. The first back casing 52 of the embodiment can be made of metal or plastics.

The second back casing 53 is also disposed on the second surface 32 of the circuit board 3, and can be connected to the first back casing 52. The second back casing 53 is used to fix a heat dissipating device 6. The second back casing 53 includes a plurality of second fixing elements 531 and an opening 532. The second fixing element 531 is shaped like a trough, but not for limiting the scope of the invention. The second fixing elements 531 are disposed corresponding to the second fixing holes 34 of the circuit board 3, and can be passed through the second fixing holes 34. The opening 532 is disposed corresponding to the openings 522 of the first back casing 52. The second back casing 53 in the embodiment can be made of metal or plastics. The second back casing 53 can be varied in size or shape according to various designs or various heat dissipating devices 6 (such as the model of LGA 1366 or LGA 2011 produced by Intel Corporation).

The heat dissipating device 6 is disposed on the first surface 31 of the circuit board 3 and corresponding to the electronic device 4 for dissipating the heat generated by the electronic device 4. The heat dissipating device 6 includes heat dissipating fins 61 and a plurality of position limiting elements 62. In other embodiments, a fan can also be used to dissipate the heat. The position limiting elements 62 can be passed through the second fixing holes 34 and the second fixing elements 531, so that the heat dissipating device 6 can be fixed to the circuit board 3. The position limiting element 62 can be illustrated as a screw or other elements for fixing or position limiting.

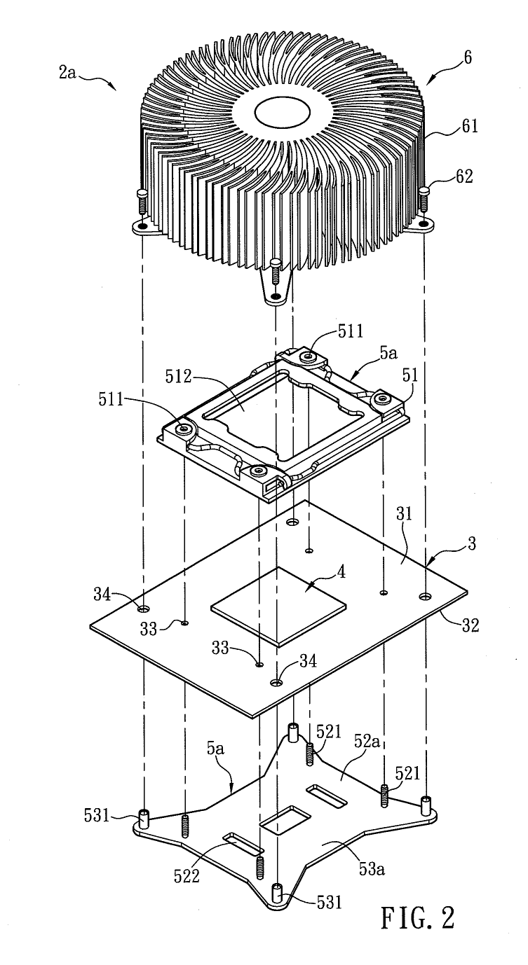

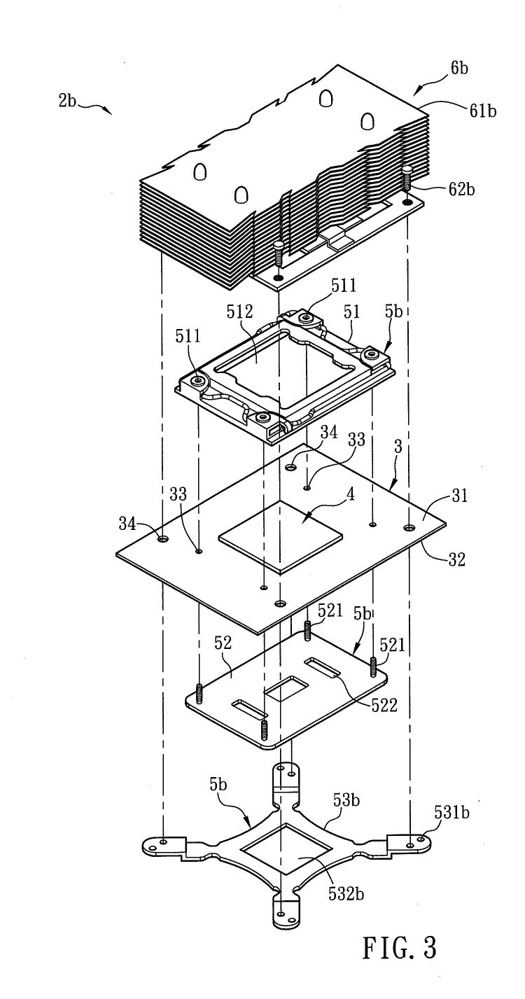

FIGS. 2 and 3 are exploded diagrams of different aspects of the mother board. As shown in FIG. 2, the first back casing 52a and the second back casing 53a are integrally formed as one piece. As shown in FIG. 3, the second back casing 53b has different shape from the second back casings 53 and 53a.

By the various combinations of the first back casings 52, 52a, 52b and the second back casings 53, 53a, 53b, the fixing modules 5, 5a, 5b can be used to fix the heat dissipating devices 6 and 6b of different types (such as the model of LGA 1366 or LGA 2011 produced by Intel Corporation), so that the electronic device 4 can be provided with the best heat dissipating efficiency.

As shown in FIG. 2, the first back casing 52a and the second back casing 53a are integrally formed as one piece. In the embodiment, the mother boards 2 and 2a each cooperate with the heat dissipating device 6 of the LGA 2011 model, so that the size and the shape of the second fixing elements 531 of the second back casings 53 and 53a are corresponding to the position limiting elements 62 of the heat dissipating device 6 of the LGA 2011 model. Hence, the position limiting elements 62 of the heat dissipating device 6 of the LGA 2011 model can be connected to the second fixing elements 531 of the second back casings 53 and 53a.

As shown in FIG. 3, the second back casing 53b of the fixing module 5b has different shape from the second back casing 53 of the fixing module 5 as shown in FIG. 1, and besides, the opening 532b has different shape and size from the opening 532. In the embodiment, the second fixing element 531b is illustrated as a hole, but not for limiting the scope of the invention. Besides, the size of the hole of the second fixing element 531b is different from that of the trough of the second fixing element 531. In one embodiment, the hole of the second fixing element 531b has smaller size than the trough of the second fixing element 531, and that means the heat dissipating devices 6 and 6b respectively used in the mother boards 2 and 2b are different types.

For the mother board 2b, the heat dissipating device 6b of the LGA 1366 model is used to dissipate the heat generated by the electronic device 4. The heat dissipating device 6b also has heat dissipating fins 61b and a plurality of position limiting elements 62b. Besides, in other embodiments, a fan can be used to dissipate the heat. The position limiting elements 62b can be connected to the second fixing elements 531b through the second fixing holes 34 to fix the circuit board 3. The position limiting element 62b can be a screw or other elements for fixing and position limiting. The shape and size of the position limiting element 62b is designed according to the second fixing element 531b.

The present invention also discloses a fixing module for fixing an electronic device and a heat dissipating device to a circuit board. The fixing module includes an upper casing, a first back casing, and a second back casing. The upper casing has a plurality of holes. The first back casing is disposed opposite to the upper casing, and has a plurality of first fixing elements connecting to the holes. The second back casing is connected to the first back casing, and has a plurality of second fixing elements. The upper casing, the first back casing, and the second back casing have the same technical features respectively as the upper casing 51, the first back casings 52 and 52a, and the second back casings 53, 53a and 53b as mentioned in the above embodiments, so the detailed descriptions are omitted here.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A mother board, comprising:
a circuit board including a first surface, a second surface, a plurality of first fixing holes, and a plurality of second fixing holes;
an electronic device disposed on the first surface; and
a fixing module including:
an upper casing disposed on the first surface and including a plurality of holes;
a first back casing disposed on the second surface and including a plurality of first fixing elements which are passed through the first fixing holes to connect to the holes of the upper casing; and
a second back casing disposed on the second surface and including a plurality of second fixing elements which are connected to the second fixing holes.

2. The mother board as recited in claim 1, wherein the first fixing holes are disposed adjacent to the electronic device.

3. The mother board as recited in claim 1, wherein the electronic device is a central processing unit (CPU).

4. The mother board as recited in claim 1, wherein the first back casing and the second back casing are integrally formed as one piece.

5. The mother board as recited in claim 1, wherein the first back casing and the second back casing are separate pieces.

6. The mother board as recited in claim 1, wherein the first fixing elements are screws, and the second fixing elements are troughs.

7. The mother board as recited in claim 1, further comprising:
a heat dissipating device connected to the second fixing elements through the second fixing holes.

8. A fixing module for fixing an electronic device and a heat dissipating device to a circuit board, the fixing module comprising:
an upper casing including a plurality of holes;
a first back casing disposed opposite to the upper casing and including a plurality of first fixing elements which are connected to the holes of the upper casing; and
a second back casing connected to the first back casing and including a plurality of second fixing elements.

9. The fixing module as recited in claim 8, wherein the electronic device is a central processing unit (CPU).

10. The fixing module as recited in claim 8, wherein the first back casing and the second back casing are integrally formed as one piece.

11. The fixing module as recited in claim 8, wherein the first back casing and the second back casing are separate pieces.

12. The fixing module as recited in claim 8, wherein the first fixing elements are screws, and the second fixing elements are troughs or holes.
